(19) United States
(12) Patent Application Publication
(10) Pub. No.: US 2025/0210570 A1
(43) Pub. Date: Jun. 26, 2025

(54) SEMICONDUCTOR PACKAGE

(71) Applicant: Samsung Electronics Co., Ltd., Suwon-si (KR)

(72) Inventors: Hakmin Kim, Suwon-si (KR); INHEE YOO, Suwon-si (KR)

(21) Appl. No.: 18/782,187

(22) Filed: Jul. 24, 2024

(30) Foreign Application Priority Data
Dec. 20, 2023 (KR) 10-2023-0187581
Jan. 24, 2024 (KR) 10-2024-0010866

(51) Int. Cl. H01L 23/00; H01L 23/31; H01L 25/065; H10B 80/00

(52) U.S. Cl. CPC H01L 24/26; H01L 23/3135; H01L 24/32; H01L 24/48; H01L 24/73; H01L 25/0657; H01L 2224/26145; H01L 2224/26175; H01L 2224/32145; H01L 2224/32225; H01L 2224/48145; H01L 2224/48227; H01L 2224/73265; H01L 2225/06506; H01L 2225/0651; H01L 2225/06562; H01L 2924/1431; H01L 2924/1436; H10B 80/00

(57) ABSTRACT

A semiconductor package includes: a package substrate that includes a substrate pad; a semiconductor chip that is disposed on the package substrate, the semiconductor chip including a chip pad; a bonding wire that connects the substrate pad to the chip pad; an adhesive member between the package substrate and the semiconductor chip; and a dam that extends along a side surface of the adhesive member and surrounds at least some of side surfaces of the adhesive member. A height of the dam is greater than or equal to a height of the adhesive member.

### CROSS-REFERENCE TO RELATED APPLICATIONS

This application claims priority to and the benefit of Korean Patent Application No. 10-2023-0187581 filed at the Korean Intellectual Property Office on Dec. 20, 2023, and Korean Patent Application No. 10-2024-0010866 filed in the Korean Intellectual Property Office on Jan. 24, 2024, the entire contents of which are incorporated herein by reference.

### BACKGROUND OF THE DISCLOSURE

### 1. Field

The present disclosure relates to a semiconductor package.

### 2. Description of the Related Art

A demand for high capacity, thinning, and miniaturization of a semiconductor device and an electronic product using the semiconductor device has increased in a semiconductor industry, so that various package technologies related to the demand emerge. For example, a semiconductor chip may be attached to a printed circuit board using an adhesive film such as a die attach film (DAF) through a die attach process.

Accordingly, a semiconductor package for preventing the die attach film that attaches the semiconductor chip to the printed circuit board from being peeled off is desirable.

### SUMMARY

Aspects of the inventive concept may provide a semiconductor package with improved reliability and productivity.

A semiconductor package according to an embodiment includes: a package substrate including a substrate pad; a semiconductor chip on the package substrate, the semiconductor chip including a chip pad; a bonding wire that connects the substrate pad to the chip pad; an adhesive member between the package substrate and the semiconductor chip; and a dam extending along a side surface of the adhesive member and surrounding at least some of side surfaces of the adhesive member, wherein a height of the dam is greater than or equal to a height of the adhesive member.

A semiconductor package according to another embodiment includes: a package substrate including a substrate pad; a first semiconductor chip on the package substrate, the first semiconductor chip including a first chip pad; a first adhesive member between the first semiconductor chip and the package substrate; a first bonding wire connecting the substrate pad to the first chip pad; a second semiconductor chip including a second chip pad, the second semiconductor chip being on the first semiconductor chip; a second adhesive member between the first semiconductor chip and the second semiconductor chip; a second bonding wire connecting the first chip pad to the second chip pad; and a dam bordering at least one of side surfaces of the first adhesive member and side surfaces of the second adhesive member.

A semiconductor package according to another embodiment includes: a package substrate including a substrate pad; a semiconductor chip on the package substrate, the semiconductor chip including a chip pad; a bonding wire that connects the substrate pad to the chip pad; an adhesive member between the package substrate and the semiconductor chip; a dam extending along a side surface of the adhesive member and surrounding at least some of side surfaces of the adhesive member; and a molding member that entirely covers the semiconductor chip and the dam, wherein the dam includes a metal material, a height of the dam is greater than or equal to a height of the adhesive member, and a side surface of the dam includes a curved surface.

According to the embodiments, moisture absorption of an adhesive member may be suppressed by forming a dam structure surrounding at least a portion of side surfaces of an adhesive film disposed between a semiconductor chip and a package substrate.

Accordingly, reliability and productivity of a semiconductor package may be improved by preventing a peeling defect due to the moisture absorption of the adhesive member or the like.

### BRIEF DESCRIPTION OF THE DRAWINGS

FIG. 1 is a plan view of a semiconductor package according to an embodiment.

FIG. 2 is a cross-sectional view cut along a line I-I′ of FIG. 1.

FIG. 3 is a partial enlarged view of a region P1 of FIG. 2.

FIG. 4 is a partially enlarged view showing a region P2 corresponding to the region P1 of FIG. 2 according to some embodiments.

FIG. 5 is a partially enlarged view showing a region P3 corresponding to the region P1 of FIG. 2 according to some embodiments.

FIGS. 6 to 8 are plan views of semiconductor packages according to some embodiments.

FIG. 9 is a plan view of a semiconductor package according to some embodiments.

FIG. 10 is a cross-sectional view cut along a line I-I′ of FIG. 9.

FIG. 11 is a partial enlarged view of a region P4 of FIG. 10.

FIGS. 12 to 15 are cross-sectional views of semiconductor packages according to some embodiments.

### DETAILED DESCRIPTION

Embodiments of the present disclosure will be described more fully hereinafter with reference to the accompanying drawings so that those skilled in the art easily implement the embodiments. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thickness of layers, films, panels, regions, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

An item, layer, or portion of an item or layer described as “extending” or as extending “lengthwise” in a particular direction has a length in the particular direction and a width perpendicular to that direction, where the length is greater than the width.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

The various pads described herein may generally have a planar upper surface having horizontal dimensions (e.g., in both the X and Y directions) that are both larger than wiring to which the pad is connected to facilitate connections thereto (e.g., to provide a larger surface to contact with a later formed via). For example, a horizontal wiring may be integrally formed with a pad (e.g., patterned out of the same metal layer) such that the wiring and pad have coplanar upper surfaces, with both of the X and Y horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have a symmetrical shape (e.g., a square or rectangular footprint) and may have X and Y horizontal dimensions that are about the same (e.g., within half to two times of the other).

It will be understood that when an element is referred to as being “directly connected” or “directly coupled” to another element, or as “contacting” or “in contact with” another element (or using any form of the word “contact”), there are no intervening elements present at the point of contact.

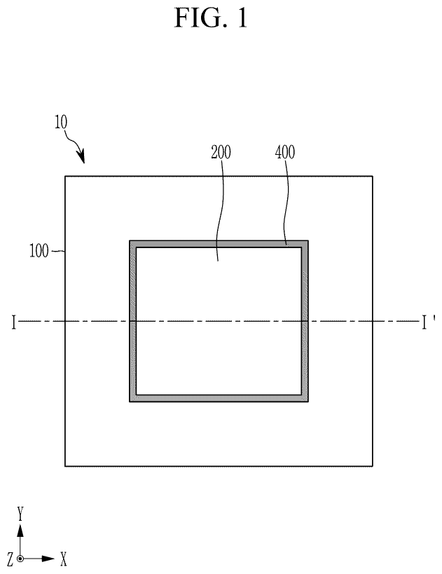

Hereinafter, a semiconductor package according to an embodiment will be described with reference to FIGS. 1 to 3.

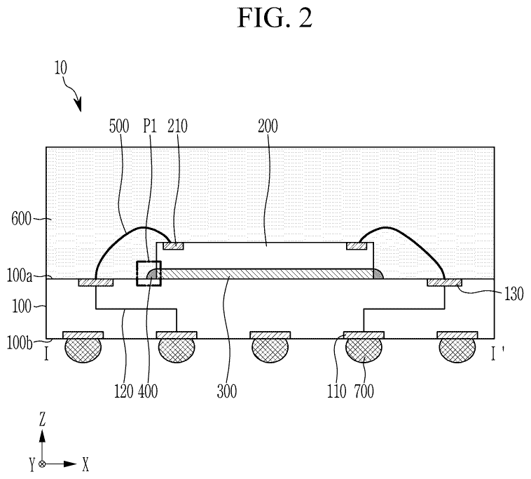

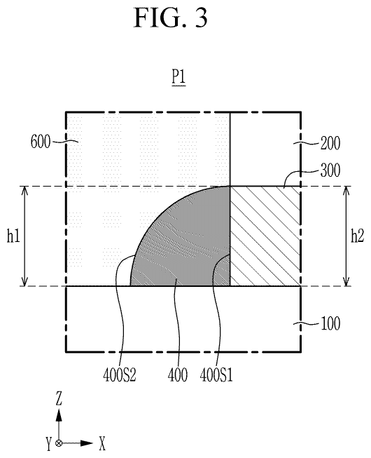

FIG. 1 is a plan view of a semiconductor package according to an embodiment. FIG. 2 is a cross-sectional view cut along a line I-I′ of FIG. 1. FIG. 3 is a partial enlarged view of a region P1 of FIG. 2.

Referring to FIGS. 1 to 3, the semiconductor package 10 according to the embodiment may include a package substrate 100, a semiconductor chip 200, an adhesive member 300, a dam structure 400 (e.g., a dam), a bonding wire 500, a molding member 600, and an external connection terminal 700.

The package substrate 100 may include a lower substrate pad 110, a connection wire 120, and an upper substrate pad 130.

The package substrate 100 may include a first surface 100a and a second surface 100b facing each other. A direction parallel to the first surface 100a of the package substrate 100 may be defined as a first direction X, a direction parallel to the first surface 100a of the package substrate 100 and perpendicular to the first direction X may be defined as a second direction Y, and a direction perpendicular to the first surface 100a of the package substrate 100 may be defined as a third direction Z.

In an embodiment, the package substrate 100 may be a printed circuit board (PCB). However, the package substrate 100 is not limited thereto, and may be variously changed. For example, the package substrate 100 may be a redistribution substrate in which at least one or more insulation layers and at least one or more conductive pads or conductive wires are stacked.

As another example, the package substrate 100 may be a ceramic substrate. As another example, the package substrate 100 may be a substrate for a wafer level package (WLP) or a substrate for a package level package (PLP).

The package substrate 100 may include an insulating material. For example, the package substrate 100 may include any one of a phenolic resin, an epoxy resin, a prepreg, and a combination thereof. However, a material included in the package substrate 100 is not limited thereto, and may be variously changed.

The lower substrate pad 110 may be disposed on the second surface 100b of the package substrate 100, and the upper substrate pad 130 may be disposed on the first surface 100a of the package substrate 100.

Specifically, the lower substrate pad 110 may be disposed within the package substrate 100, and a lower surface of the lower substrate pad 110 may be coplanar with the second surface 100b of the package substrate 100. However, a position of the lower substrate pad 110 is not limited thereto, and may be variously changed. For example, the lower substrate pad 110 may be disposed on the second surface 100b of the package substrate 100.

The upper substrate pad 130 may be disposed within the package substrate 100, and an upper surface of the upper substrate pad 130 may be coplanar with the first surface 100a of the package substrate 100. However, a position of the upper substrate pad 130 is not limited thereto, and may be variously changed. For example, the upper substrate pad 130 may be disposed on the first surface 100a of the package substrate 100.

Each of the lower substrate pad 110 and the upper substrate pad

130 may include a conductive material. For example, each of the lower substrate pad 110 and the upper substrate pad 130 may include any one of a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like and an alloy thereof. However, a material included in each of the lower substrate pad 110 and the upper substrate pad 130 is not limited thereto, and may be variously changed.

The connection wire 120 may be disposed within the package substrate 100. The connection wire 120 may connect the lower substrate pad 110 to the upper substrate pad 130. For example, the connection wire 120 may electrically connect at least one of a plurality of lower substrate pads 110 to the upper substrate pad 130.

Here, a connection between the lower substrate pad 110 and the upper substrate pad 130 may include a direct connection between the lower substrate pad 110 and the upper substrate pad 130 or an indirect connection between the lower substrate pad 110 and the upper substrate pad 130 through another component.

Although FIG. 2 shows that the lower substrate pad 110 and the upper substrate pad 130 are electrically connected by the connection wire 120, a connection relationship between the lower substrate pad 110 and the upper substrate pad 130 is not limited thereto, and may be variously changed.

The connection wire 120 may include a conductive material. For example, the connection wire 120 may include any one of copper (Cu), aluminum (Al), tungsten (W), nickel (Ni), titanium (TiN), titanium nitride (TiN), tantalum (Ta), tantalum nitride (TaN), gold (Au), and a combination thereof. However, a material included in the connection wire 120 is not limited thereto, and may be variously changed.

Although FIG. 2 shows that the package substrate 100 is made of a single layer, the present disclosure is not limited thereto, and the package substrate 100 may be made of a plurality of insulating layers sequentially stacked. For example, the package substrate 100 may be made of a plurality of insulating layers including a photo-imageable dielectric (PID) insulating material capable of performing a photoresist process.

Additionally, although FIG. 2 shows that the package substrate 100 includes the lower substrate pad 110, the upper substrate pad 130, and the connection wire 120 connecting the lower substrate pad 110 to the upper substrate pad 130, a configuration included in the package substrate 100 is not limited thereto, and may be variously changed.

For example, the package substrate 100 may further include a conductive pattern including a conductive via and a conductive wire in addition to the lower substrate pad 110, the upper substrate pad 130, and the connection wire 120. For example, the package substrate 100 may further include the conductive pattern disposed between the lower substrate pad 110 and the upper substrate pad 130, and the lower substrate pad 110 and the upper substrate pad 130 may be electrically connected to each other by the conductive via and the conductive wire.

The external connection terminal 700 may be disposed on the lower substrate pad 110. The external connection terminal 700 may be disposed to be protruded above (e.g., below as shown in FIG. 2) the second surface 100b of the package substrate 100, and may be connected to the lower substrate pad 110.

For example, the external connection terminal 700 may be at least one of a solder ball, a pillar, and a bump. Depending on a type of the external connection terminal 700, the package substrate 100 may include a form of a ball grid array (BGA), a fine ball-grid array (FBGA), or a land grid array (LGA). However, a type and a form of the external connection terminal 700 are not limited thereto, and may be variously changed.

The external connection terminal 700 may include a conductive material. For example, the external connection terminal 700 may include any one of a metal such as tin (Sn), silver (Ag), zinc (Zn), lead (Pb), or the like and an alloy thereof. However, the conductive material included in the external connection terminal 700 is not limited thereto, and may be variously changed.

The semiconductor package 10 according to the embodiment may be electrically connected to and mounted on a module substrate, a system board, or the like of an electronic product through the external connection terminal 700. The lower substrate pad 110 may serve as an under bump metallurgy (UBM) where the external connection terminal 700 is disposed.

The semiconductor chip 200 may be installed on the first surface 100a of the package substrate 100. The semiconductor chip 200 may include a lower surface facing the package substrate 100 and an upper surface facing in the third direction Z perpendicular to the lower surface (e.g., the upper surface may be opposite to the lower surface).

The upper surface of the semiconductor chip 200 may be an active surface. For example, the semiconductor chip 200 may be installed so that the lower surface thereof faces the first surface 100a of the package substrate 100.

The semiconductor chip 200 may include a chip pad 210 and an integrated circuit (not shown). The chip pad 210 may be disposed on the upper surface that is the active surface of the semiconductor chip 200, and an upper surface of the chip pad 210 may be coplanar with the upper surface of the semiconductor chip 200. However, a position of the chip pad 210 and the number of chip pads 210 are not limited thereto, and may be variously changed. For example, the chip pad 210 may be disposed on the upper surface of the semiconductor chip 200.

The integrated circuit may be disposed within the semiconductor chip 200. The chip pad 210 may be electrically connected to the integrated circuit.

The semiconductor chip 200 may be a memory chip or a logic chip. For example, the memory chip may be a volatile memory chip such as a dynamic random access memory (DRAM) or a static random access memory (SRAM), or a nonvolatile memory chip such as a phase-change random access memory (PRAM), a magnetoresistive random access memory (MRAM), a ferroelectric random access memory (FeRAM), or a resistive random access memory (RRAM).

In some embodiments, the memory chip may be a high bandwidth memory (HBM) DRAM semiconductor chip. Additionally, the logic chip may be a microprocessor, an analog device, or a digital signal processor. However, a type of the semiconductor chip 200 is not limited thereto, and may be variously changed.

For example, the chip pad 210 may include a ground pad, a power pad, an AC pad, a data pad, and a DC pad. The ground pad may be a pad for providing a reference potential for a circuit operation of the semiconductor chip. The power pad may be a pad for supplying power for the circuit operation. The AC pad may be a pad that supplies AC power to the semiconductor chip or receives a signal for performing an AC test. The data pad may be a pad for input/output of a logical signal or data. The DC pad may be a pad for measuring a potential level of a specific position of the semiconductor chip. However, a type and a function of the chip pad 210 are not limited thereto, and may be variously changed.

The chip pad 210 may include a conductive material. For example, the chip pad 210 may include any one of a metal such as aluminum (Al), titanium (Ti), chromium (Cr), iron (Fe), cobalt (Co), nickel (Ni), copper (Cu), zinc (Zn), lead (Pb), platinum (Pt), gold (Au), or silver (Ag) and an alloy thereof.

In an embodiment, the semiconductor chip 200 may be installed on the package substrate 100 by a wire bonding method.

Specifically, the package substrate 100 and the semiconductor chip 200 may be electrically connected to each other by the bonding wire 500. The bonding wire 500 may be connected to the chip pad 210 of the semiconductor chip 200 and the upper substrate pad 130 of the package substrate 100.

One end portion of the bonding wire 500 may be connected to the upper substrate pad 130 of the package substrate 100, and the other end portion of the bonding wire 500 may be connected to the chip pad 210 of the semiconductor chip 200.

Although FIG. 2 shows that the package substrate 100 and the semiconductor chip 200 are connected to each other by the wire bonding method, a connection relationship between the package substrate 100 and the semiconductor chip 200 is not limited thereto, and may be variously changed. For example, the package substrate 100 and the semiconductor chip 200 may be connected by a connection terminal such as a solder ball or the like. As another example, the semiconductor chip 200 may be directly connected to the package substrate 100.

The bonding wire 500 may include a conductive material. For example, the bonding wire 500 may include silver (Ag), copper (Cu), gold (Au), aluminum (Al), or an alloy thereof. However, a material included in the bonding wire 500 is not limited thereto, and may be variously changed.

The adhesive member 300 may be disposed between the package substrate 100 and the semiconductor chip 200.

The semiconductor chip 200 may be adhered to the package substrate 100 by the adhesive member 300. An upper surface of the adhesive member 300 may be in contact with a lower portion surface of the semiconductor chip 200, and a lower portion surface of the adhesive member 300 may be in contact with the first surface 100a of the package substrate 100. However, the present disclosure is not limited thereto, and in some embodiments, another layer may be further disposed between the package substrate 100 and the adhesive member 300 and/or between the semiconductor chip 200 and the adhesive member 300.

A width of the adhesive member 300 along the first direction X and the second direction Y may be substantially the same as a width of the semiconductor chip 200 along the first direction X and the second direction Y. That is, an end of the adhesive member 300 may be aligned at substantially the same boundary as that of an end of the semiconductor chip 200. However, a relationship between the widths of the semiconductor chip 200 and the adhesive member 300 is not limited thereto, and may be variously changed. For example, a width of the adhesive member 300 along the first direction X and/or the second direction Y may be different from a width of the semiconductor chip 200 along the first direction X and/or the second direction Y.

In an embodiment, the adhesive member 300 may be a die attach film. For example, the adhesive member 300 may include an insulating material. However, a type and a material of the adhesive member 300 are not limited thereto, and may be variously changed.

The dam structure 400 may be disposed on the first surface 100a of the package substrate 100. The dam structure 400 may be disposed outside the adhesive member 300 (e.g., bordering the adhesive member 300), and may extend along a side surface of the adhesive member 300. The dam structure 400 may surround at least a portion of the adhesive member 300.

In an embodiment, the dam structure 400 may extend along an outer circumference of the adhesive member 300, and may surround all side surfaces of the adhesive member 300 on a plane. The dam structure 400 may extend in the first direction X and the second direction Y on a plane along the side surfaces of the adhesive member 300, and may be in contact with the side surfaces of the adhesive member 300.

Specifically, the dam structure 400 may include a first side surface 400S1 and a second side surface 400S2 opposite to each other in the first direction X. The first side surface 400S1 of the dam structure 400 may be in contact with the side surface of the adhesive member 300.

The first side surface 400S1 of the dam structure 400 may extend along the side surface of the adhesive member 300 in the third direction Z that is a direction perpendicular to the first surface 100a of the package substrate 100, and may have a straight line shape when viewed in cross-section as shown, e.g., in FIG. 3.

The second side surface 400S2 of the dam structure 400 may have a curved shape. That is, the second side surface 400S2 of the dam structure 400 may have a rounded shape so as to approach the package substrate 100 from the side surface of the adhesive member 300. In other words, the second side surface 400S2 of the dam structure 400 may have the curved shape convex in a direction away from the first side surface 400S1. For example, when viewed in cross-section in the X-Z plane as shown in FIG. 3, the second side surface 400S2 may have the shape of an arc extending from a side of the adhesive member 300 to the first surface 100a of the package substrate 100. However, a shape of the second side surface 400S2 of the dam structure 400 is not limited thereto, and may vary depending on a material included in the dam structure 400 and a method of forming the dam structure 400. For example, the second side surface 400S2 of the dam structure 400 may have a side surface inclined with respect to the package substrate 100, and the dam structure 400 may have a triangle shape in a cross-section. As another example, the dam structure 400 may have a quadrangle shape in a cross-section.

A width of the dam structure 400 along the first direction X may have a shape that becomes wider as it approaches the package substrate 100. In other words, a distance between the first side surface 400S1 and the second side surface 400S2 of the dam structure 400 may become greater as it approaches the package substrate 100.

A height of the dam structure 400 at an uppermost portion thereof along the third direction Z may be substantially the same as a height of the adhesive member 300 along the third direction Z, or may be greater than the height of the adhesive member 300 along the third direction Z.

Specifically, the dam structure 400 may have a first height h1, and the adhesive member 300 may have a second height h2. Here, the first height h1 of the dam structure 400 refers to a height of the first side surface 400S1 of the dam structure 400 along the third direction Z, and the second height h2 of the adhesive member 300 refers to a height of the side surface of the adhesive member 300 along the third direction Z.

In an embodiment, the first height h1 may be substantially the same as the second height h2. That is, one end of the first side surface 400S1 and one end of the second side surface 400S2 of the dam structure 400 may be in contact with a side surface end of the adhesive member 300. In other words, the one end of the first side surface 400S1 and the one end of the second side surface 400S2 of the dam structure 400 may be disposed at substantially the same level as that of the upper surface of the adhesive member 300.

Additionally, the dam structure 400 may not be in contact with the semiconductor chip 200. That is, because the one end of the first side surface 400S1 and the one end of the second side surface 400S2 of the dam structure 400 are disposed at substantially the same level as that of the upper surface of the adhesive member 300, the dam structure 400 may not be in contact with a side surface of the semiconductor chip 200. In other words, the dam structure 400 may not overlap the semiconductor chip 200 in the first direction X that is a direction parallel to the package substrate 100.

Accordingly, the dam structure 400 may entirely cover the side surface of the adhesive member 300. That is, the side surface of the adhesive member 300 may be entirely covered by the dam structure 400, and the adhesive member 300 may be sealed by the dam structure 400.

In an embodiment, the dam structure 400 may include a metal material. For example, the dam structure 400 may include any one of a metal such as copper (Cu), tin (Sn), silver (Ag), aluminum (Al), titanium (Ti), chromium (Cr), iron (Fe), cobalt (Co), nickel (Ni), zinc (Zn), lead (Pb), platinum (Pt), or gold (Au) and an alloy thereof. However, a metal material included in the dam structure 400 is not limited thereto, and may be variously changed.

In some embodiments, the dam structure 400 may include a moisture absorbent. For example, the moisture absorbent may be a compound in which metals are linked by oxygen such as calcium oxide, barium oxide, aluminum oxide, magnesium oxide, or the like, and may include a material that reacts with water to form a metal hydroxide.

As another example, the moisture absorbent may include any one selected from the group consisting of metal halide, an inorganic acid salt of a metal, an organic acid salt of a metal, a porous inorganic compound, and a combination thereof.

As another example, the moisture absorbent may include an acryl-based organic material, a methacryl-based organic material, a polyisoprene-based organic material, a vinyl-based organic material, an epoxy-based organic material, a urethane-based organic material, or a cellulose-based organic material.

As another example, the moisture absorbent may include a titania-based inorganic material, a silicon oxide-based inorganic material, a zirconia-based inorganic material, or an alumina-based inorganic material, or may include a sealant made of epoxy silane, vinyl silane, amine silane, or methacrylate silane.

If the dam structure 400 covering the side surface of the adhesive member 300 includes the moisture absorbent, it may physically block moisture from permeating from the outside of the semiconductor package 10 through the molding member 600 to the adhesive member 300, and at the same time, it may effectively prevent the adhesive member 300 from absorbing moisture.

In some embodiments, the dam structure 400 may include an elastic material that is compressed if a pressure is applied to absorb or relieve external shock or stress and is restored to its original shape if the pressure is released. For example, the dam structure 400 may include a polymer resin such as an epoxy resin, silicon, polyurethane, polycarbonate, polypropylene, polyethylene, or the like.

As another example, the dam structure 400 may include a material with elasticity such as a rubber, a sponge foaming and molding a urethane-based material or an acryl-based material, or the like. However, a material included in the dam structure 400 is not limited thereto, and may be variously changed.

Additionally, the dam structure 400 may include a material with a relatively low modulus to absorb or alleviate external impact or stress.

Here, the modulus may mean a Young's modulus. When a pressure is applied to an object, the smaller the Young's modulus, the greater the degree of deformation of the object.

For example, the dam structure 400 may include a material having a modulus lower than those of the semiconductor chip 200 and the adhesive member 300. As another example, the dam structure 400 may include a material having a modulus lower than that of the semiconductor chip 200 and higher than that of the adhesive member 300.

If the dam structure 400 covering the side surface of the adhesive member 300 includes the elastic material or the material with the relatively low modulus, it may physically block moisture from permeating from the outside of the semiconductor package 10 through the molding member 600 to the adhesive member 300, and at the same time, it may relieve or absorb a stress caused by a difference in a coefficient of thermal expansion between the package substrate 100, the semiconductor chip 200, and the adhesive member 300.

The molding member 600 may be disposed on the first surface 100a of the package substrate 100. The molding member 600 may cover the first surface 100a of the package substrate 100, the semiconductor chip 200, the dam structure 400, and the bonding wire 500.

The molding member 600 may entirely cover the dam structure 400. The dam structure 400 may be disposed between the adhesive member 300 and the molding member 600. As the dam structure 400 entirely covers the adhesive member 300, the molding member 600 may not be in contact with the adhesive member 300.

The molding member 600 may include an insulating material. For example, the molding member 600 may include a polymer such as an epoxy molding compound (EMC). As another example, the molding member 600 may include an epoxy-based material, a thermosetting material, a thermoplastic material, a UV treatment material, or the like. However, a material included in the molding member 600 is not limited thereto, and may be variously changed.

According to the semiconductor package 10 according to the embodiment, the adhesive member 300 may be sealed by the dam structure 400 that extends along an outer circumference of the adhesive member 300 and entirely surrounds side surfaces of the adhesive member 300.

Because the adhesive member 300 is sealed by the dam structure 400, the side surfaces of the adhesive member 300 may not be exposed to the outside, and the adhesive member 300 may not be in contact with the molding member 600.

Accordingly, because moisture permeating from the outside of the semiconductor package 10 through the molding member 600 to the adhesive member 300 is blocked by the dam structure 400, reliability and productivity of the semiconductor package 10 may be improved by minimizing a peeling defect due to moisture absorption of the adhesive member 300.

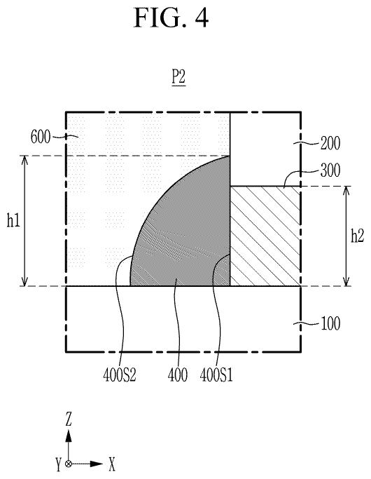

Hereinafter, a semiconductor package according to various embodiments will be described with reference to FIGS. 4 to 15. In the following embodiment, the same configuration described above will be referred to by the same reference numeral, and a redundant description will be omitted or simplified, and a difference will be mainly described.

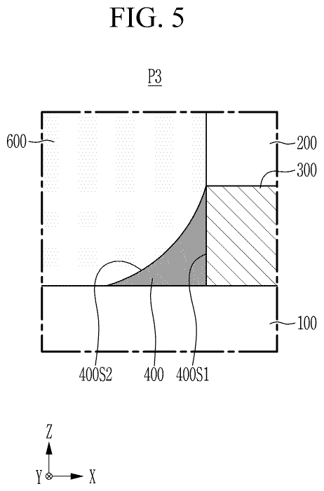

FIG. 4 is a partially enlarged view showing a region P2 corresponding to the region P1 of FIG. 2 according to some embodiments. FIG. 5 is a partially enlarged view showing a region P3 corresponding to the region P1 of FIG. 2 according to some embodiments.

According to the embodiment shown in FIG. 4, unlike the embodiment shown in FIG. 3, there is a difference in that a disposition relationship between the dam structure 400 and the semiconductor chip 200 is different.

Specifically, referring to FIG. 4, a first height h1 may be higher than a second height h2. That is, one end of the first side surface 400S1 and one end of the second side surface 400S2 of the dam structure 400 may be in contact with a side surface of the semiconductor chip 200. For example, an a height h1 of the dam structure 400 at an uppermost point of the dam structure 400 may be greater than a height h2 of the adhesive member 300.

The one end of the first side surface 400S1 and the one end of the second side surface 400S2 of the dam structure 400 may be disposed at a higher level than that of an upper surface of the adhesive member 300. For example, the one end of the first side surface 400S1 and the one end of the second side surface 400S2 of the dam structure 400 may be disposed at a level between a lower surface of the semiconductor chip 200 and an upper surface of the semiconductor chip 200.

Accordingly, the dam structure 400 may directly contact at least a portion of the side surface of the semiconductor chip 200. That is, the dam structure 400 may entirely cover a side surface of the adhesive member 300, and the dam structure 400 may cover a portion of the side surface of the semiconductor chip 200.

Although FIG. 4 shows that the dam structure 400 covers the portion of the side surface of the semiconductor chip 200, the disposition relationship between the dam structure 400 and the semiconductor chip 200 is not limited thereto, and may be variously changed. For example, the dam structure 400 may further extend in the third direction Z to entirely cover the side surface of the semiconductor chip 200. That is, the one end of the first side surface 400S1 and the one end of the second side surface 400S2 of the dam structure 400 may be disposed at substantially the same level as that of the upper surface of the semiconductor chip 200.

According to the embodiment shown in FIG. 5, unlike the embodiment shown in FIG. 3, there is a difference in that a shape of the dam structure 400 is different.

Specifically, referring to FIG. 5, the second side surface 400S2 of the dam structure 400 may have a shape different from that of the second side surface 400S2 of the dam structure 400 according to the embodiment shown in FIG. 3.

The second side surface 400S2 of the dam structure 400 may have a concave curved shape. The second side surface 400S2 of the dam structure 400 may have a concave shape in a direction approaching the first side surface 400S1. In other words, the second side surface 400S2 of the dam structure 400 may have a shape concavely recessed by the molding member 600. However, a shape of the second side surface 400S2 of the dam structure 400 is not limited thereto, and may be variously changed.

A difference between the shape of the dam structure 400 according to the present embodiment and the shape of the dam structure 400 according to the embodiment shown in FIG. 3 may be a result of a change in a material included in the dam structure 400 or a method of forming the dam structure 400. For example, in the present embodiment, the dam structure 400 may include at least one of the moisture absorbent and the elastic material.

The embodiments shown in FIG. 4 and FIG. 5 may have substantially the same effect as that of the semiconductor package 10 according to the embodiment.

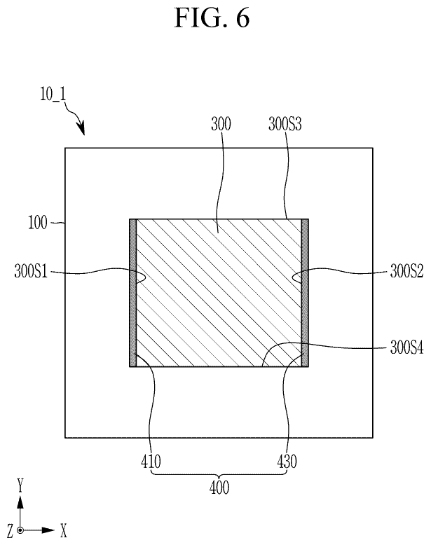

FIGS. 6 to 8 are plan views of semiconductor packages according to some embodiments.

In FIGS. 6 to 8, the semiconductor chip 200 disposed on the adhesive member 300 is omitted to clearly show a disposition relationship between the adhesive member 300 and the dam structure 400.

According to the semiconductor packages 10_1, 10_2, and 10_3 shown in FIGS. 6 to 8, unlike the semiconductor package 10 shown in FIG. 1, there is a difference in that the disposition relationship between the adhesive member 300 and the dam structure 400 is different. That is, according to the embodiments shown in FIGS. 6 to 8, the dam structure 400 may extend along some of side surfaces of the adhesive member 300, or may surround only some of the side surfaces.

Specifically, referring to FIG. 6, in the present embodiment, the adhesive member 300 may include a first side surface 300S1 and a second side surface 300S2 opposite to each other in the first direction X, and a third side surface 300S3 and a fourth side surface 300S4 opposite to each other in the second direction Y.

Each of the first side surface 300S1 and the second side surface 300S2 of the adhesive member 300 may extend in the second direction Y on the plane, and each of the third side surface 300S3 and the fourth side surface 300S4 may cross each of the first side surface 300S1 and the second side surface 300S2 to extend in the first direction X on the plane.

In the present embodiment, the dam structure 400 may be disposed outside (e.g., may border) some of the side surfaces 300S1, 300S2, 300S3, and 300S4 of the adhesive member 300. For example, the dam structure 400 may be disposed at the outsides of the first side surface 300S1 and the second side surface 300S2 of the adhesive member 300.

Although not shown in the drawings, as another example, the dam structure 400 may be disposed at the outsides of the third side surface 300S3 and the fourth side surface 300S4 of the adhesive member 300.

Hereinafter, a description will be made based on a fact that the dam structure 400 is disposed at the outsides of the first side surface 300S1 and the second side surface 300S2 of the adhesive member 300.

In the present embodiment, the dam structure 400 may include a first dam structure 410 (e.g., a first portion of the dam structure 400) disposed outside the first side surface 300S1 of the adhesive member 300 and extending in the second direction Y on a plane along the first side surface 300S1, and a second dam structure 430 (e.g., a second portion of the dam structure 400) disposed outside the second side surface 300S2 of the adhesive member 300 and extending in the second direction Y on a plane along the second side surface 300S2. The first dam structure 410 and the second dam structure 430 may be disposed to be spaced apart from each other in the first direction X with the adhesive member 300 interposed therebetween.

In the present embodiment, the first dam structure 410 may be in contact with the first side surface 300S1 of the adhesive member 300, and the second dam structure 430 may be in contact with the second side surface 300S2 of the adhesive member 300. That is, the first side surface 300S1 and the second side surface 300S2 of the adhesive member 300 may be entirely covered by the first dam structure 410 and the second dam structure 430. However, a disposition relationship between the first and second side surfaces 300S1 and 300S2 of the adhesive member 300 and the dam structure 400 is not limited thereto, and may be variously changed. For example, the first dam structure 410 and the second dam structure 430 may be disposed at a predetermined distance from the first side surface 300S1 and the second side surface 300S2 of the adhesive member 300, respectively.

In the present embodiment, each of lengths of the first dam structure 410 and the second dam structure 430 along the second direction Y may be substantially the same as each of a length of the first side surface 300S1 of the adhesive member 300 and a length of the second side surface 300S2 of the adhesive member 300 along the second direction Y. However, a length relationship between the first and second dam structures 410 and 430 and the first and second side surfaces 300S1 and 300S2 of the adhesive member 300 is not limited thereto, and may be variously changed. For example, each of lengths of the first dam structure 410 and the second dam structure 430 along the second direction Y may be greater than each of a length of the first side surface 300S1 of the adhesive member 300 and a length of the second side surface 300S2 of the adhesive member 300 along the second direction Y.

As another example, each of lengths of the first dam structure 410 and the second dam structure 430 along the second direction Y may be less than each of a length of the first side surface 300S1 of the adhesive member 300 and a length of the second side surface 300S2 of the adhesive member 300 along the second direction Y.

Accordingly, the first dam structure 410 may cover a portion of the first side surface 300S1 of the adhesive member 300, and the second dam structure 430 may cover a portion of the second side surface 300S2 of the adhesive member 300.

In the present embodiment, the first dam structure 410 and the second dam structure 430 may include the same material. However, a material included in each of the first dam structure 410 and the second dam structure 430 is not limited thereto, and may be variously changed. For example, the first dam structure 410 and the second dam structure 430 may include different materials.

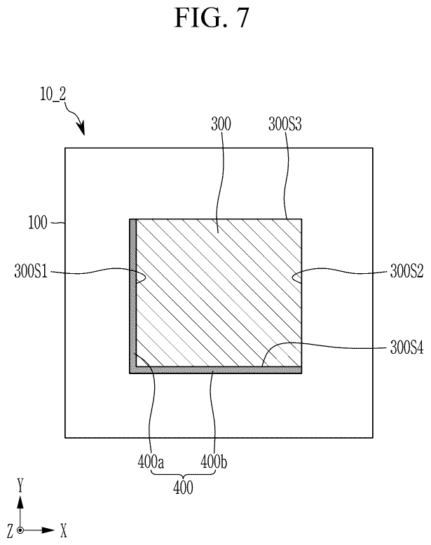

Referring to FIG. 7, in the present embodiment, the dam structure 400 may surround some of the side surfaces 300S1, 300S2, 300S3, and 300S4 of the adhesive member 300. For example, the dam structure 400 may surround the first side surface 300S1 and the fourth side surface 300S4 of the adhesive member 300.

Although not shown in the drawings, as another example, the dam structure 400 may surround the second side surface 300S2 and the third side surface 300S3 of the adhesive member 300.

Hereinafter, a description will be made based on a fact that the dam structure 400 may surround the first side surface 300S1 and the fourth side surface 300S4 of the adhesive member 300.

In the present embodiment, the dam structure 400 may be disposed outside (e.g., may border) the first side surface 300S1 and the fourth side surface 300S4 of the adhesive member 300, and may surround the first side surface 300S1 and the fourth side surface 300S4. In other words, the dam structure 400 may have an L shape on a plane.

In the present embodiment, the dam structure 400 may include a first portion 400a disposed outside the first side surface 300S1 of the adhesive member 300 and extending in the second direction Y on a plane along the first side surface 300S1, and a second portion 400b disposed outside the fourth side surface 300S4 of the adhesive member 300 and extending in the first direction X on a plane along the fourth side surface 300S4.

The first portion 400a and the second portion 400b of the dam structure 400 may be integrally formed, and there may be no boundary between the first portion 400a and the second portion 400b of the dam structure 400. However, a relationship between the first portion 400a and the second portion 400b of the dam structure 400 is not limited thereto, and may be variously changed. For example, the first portion 400a and the second portion 400b of the dam structure 400 may be configured in separate configurations. If the first portion 400a and the second portion 400b of the dam structure 400 are configured in separate configurations, there may be a boundary between the first portion 400a and the second portion 400b. For example, there may be a gap between the first portion 400a and the second portion 400b.

In the present embodiment, each of the first portion 400a and the second portion 400b of the dam structure 400 may be in contact with each of the first side surface 300S1 and the fourth side surface 300S4 of the adhesive member 300. That is, each of the first side surface 300S1 and the fourth side surface 300S4 of the adhesive member 300 may be entirely covered by each of the first portion 400a and the second portion 400b of the dam structure 400. However, a disposition relationship between the first and fourth side surfaces 300S1 and 300S4 of the adhesive member 300 and the dam structure 400 is not limited thereto, and may be variously changed. For example, the first portion 400a and the second portion 400b of the dam structure 400 may be disposed at a predetermined distance from the first side surface 300S1 and the fourth side surface 300S4 of the adhesive member 300, respectively.

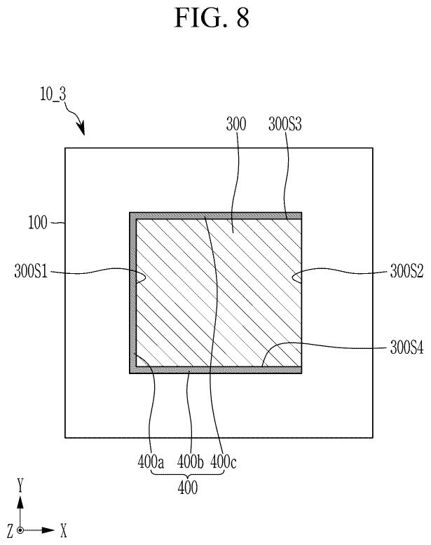

Referring to FIG. 8, in the present embodiment, the dam structure 400 may surround some of the side surfaces 300S1, 300S2, 300S3, and 300S4 of the adhesive member 300. For example, the dam structure 400 may surround the first side surface 300S1, the third side surface 300S3, and the fourth side surface 300S4 of the adhesive member 300.

Although not shown in the drawings, as another example, the dam structure 400 may surround the second side surface 300S2, the third side surface 300S3, and the fourth side surface 300S4 of the adhesive member 300.

Hereinafter, a description will be made based on a fact that the dam structure 400 surrounds the first side surface 300S1, the third side surface 300S3, and the fourth side surface 300S4 of the adhesive member 300.

In the present embodiment, the dam structure 400 may be disposed outside (e.g., may border) the first side surface 300S1, the third side surface 300S3, and the fourth side surface 300S4 of the adhesive member 300, and may surround the first side surface 300S1, the third side surface 300S3, and the fourth side surface 300S4. In other words, the dam structure 400 may have a C shape on a plane.

In the present embodiment, the dam structure 400 may include a first portion 400a disposed outside the first side surface 300S1 of the adhesive member 300 and extending in the second direction Y on a plane along the first side surface 300S1, a second portion 400b disposed outside the fourth side surface 300S4 of the adhesive member 300 and extending in the first direction X on a plane along the fourth side surface 300S4, and a third portion 400c extending in the first direction X on a plane along the third side surface 300S3 and opposite to the second portion 400b in the second direction Y.

The first portion 400a, the second portion 400b, and the third portion 400c of the dam structure 400 may be integrally formed, and there may be no boundary between the first portion 400a, the second portion 400b, and the third portion 400c of the dam structure 400. However, a relationship between the first portion 400a, the second portion 400b, and the third portion 400c of the dam structure 400 is not limited thereto, and may be variously changed. For example, at least some of the first portion 400a, the second portion 400b, and the third portion 400c of the dam structure 400 may be configured in separate configurations. If the first portion 400a, the second portion 400b, and the third portion 400c of the dam structure 400 are configured in separate configurations, there may be a boundary and/or a gap between the first portion 400a, the second portion 400b, and the third portion 400c.

In the present embodiment, each of the first to third portions 400a, 400b, and 400c of the dam structure 400 may be in contact with each of the first side surface 300S1, the third side surface 300S3, and the fourth side surface 300S4 of the adhesive member 300, respectively. That is, each of the first side surface 300S1, the third side surface 300S3, and the fourth side surface 300S4 of the adhesive member 300 may be entirely covered by each of the first to third portions 400a, 400b, and 400c of the dam structure 400. However, a disposition relationship between the first side surface 300S1, the third side surface 300S3, and the fourth side surface 300S4 of the adhesive member 300 and the dam structure 400 is not limited thereto, and may be variously changed. For example, the first to third portions 400a, 400b, and 400c of the dam structure 400 may be disposed at a predetermined distance from the first side surface 300S1, the third side surface 300S3, and the fourth side surface 300S4 of the adhesive member 300, respectively.

In the embodiments according to FIGS. 6 to 8, the dam structure 400 is shown as covering at least two of the side surfaces 300S1, 300S2, 300S3, and 300S4 of the adhesive member 300, but in some embodiments, the dam structure 400 may extend along the outside of any one of the side surfaces 300S1, 300S2, 300S3, and 300S4 of the adhesive member 300. That is, the dam structure 400 may cover any one of the side surfaces 300S1, 300S2, 300S3, and 300S4 of the adhesive member 300.

According to the semiconductor packages 10_1, 10_2, and 10_3 shown in FIGS. 6 to 8, the dam structure 400 may cover some of the side surfaces of the adhesive member 300 by forming the dam structure 400 on the side surface or some of the side surfaces vulnerable to moisture absorption among the side surfaces of the adhesive member 300.

Accordingly, because moisture permeating from the outside of the semiconductor packages 10_1, 10_2, and 10_3 through the molding member 600 to the adhesive member 300 is minimized, the semiconductor packages 10_1, 10_2, and 10_3 may have substantially the same effect as that of the semiconductor package 10 according to the embodiment.

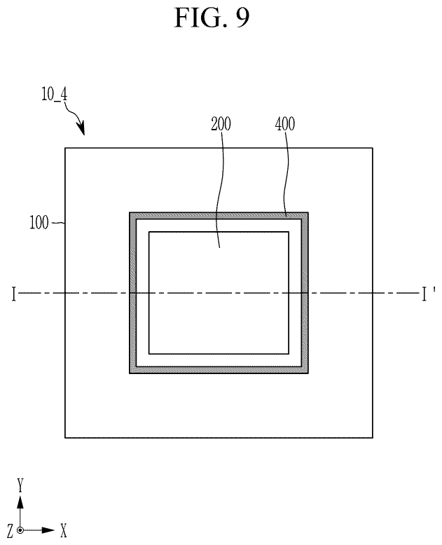

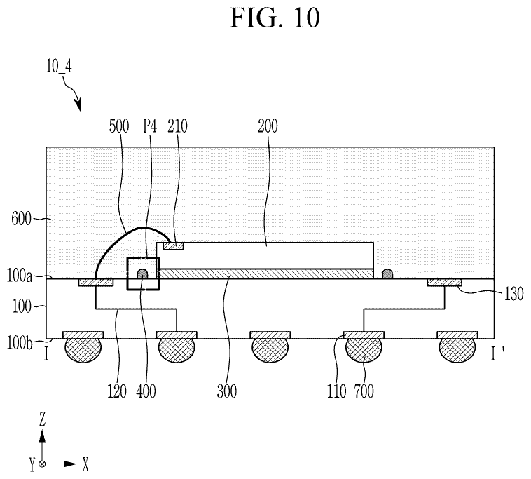

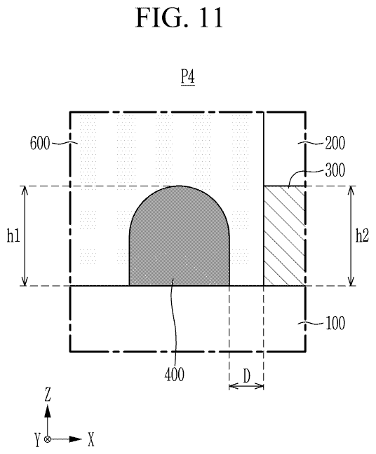

FIG. 9 is a plan view of a semiconductor package according to some embodiments. FIG. 10 is a cross-sectional view cut along a line I-I′ of FIG. 9. FIG. 11 is a partial enlarged view of a region P4 of FIG. 10.

According to the semiconductor package 10_4 shown in FIGS. 9 to 11, unlike the semiconductor package 10_1 according to the embodiment, there is a difference in that a disposition relationship between the adhesive member 300 and the dam structure 400 is different. That is, according to the embodiment shown in FIGS. 9 to 11, the dam structure 400 may be disposed at a predetermined distance from the adhesive member 300.

Referring to FIGS. 9 to 11, in the present embodiment, the dam structure 400 may be disposed to be spaced apart from the adhesive member 300, and may extend along an outer circumference of the adhesive member 300.

Because the dam structure 400 is disposed to be spaced apart from the adhesive member 300, a gap region may be defined between the dam structure 400 and the adhesive member 300. The gap region between the dam structure 400 and the adhesive member 300 may be defined by a side surface of the dam structure 400, a side surface of the adhesive member 300, and a first surface 100a of the package substrate 100.

The molding member 600 may be disposed in the gap region between the dam structure 400 and the adhesive member 300. The molding member 600 may entirely cover an upper portion surface and both side surfaces of the dam structure 400. Additionally, the molding member 600 may entirely cover a side surface of the semiconductor chip 200 and the side surface of the adhesive member 300.

Accordingly, side surfaces of the adhesive member 300 may face each other in the first direction X that is a direction parallel to the first surface 100a of the package substrate 100 and the dam structure 400. That is, at least some of the side surfaces of the adhesive member 300 may overlap the dam structure 400 in the first direction X.

In the present embodiment, the dam structure 400 may be disposed to be spaced apart from the adhesive member 300 along the first direction X that is the direction parallel to the first surface 100a of the package substrate 100.

Specifically, a separation distance D between the adhesive member 300 and the dam structure 400 may be about 20 μm to 30 μm. Here, the separation distance between the adhesive member 300 and the dam structure 400 means a distance along the first direction X between the side surface of the adhesive member 300 and the side surface of the dam structure 400 facing each other. However, the separation distance D between the adhesive member 300 and the dam structure 400 is not limited thereto, and may be variously changed.

If the separation distance D between the adhesive member 300 and the dam structure 400 has the above numerical range, a process margin for forming the dam structure 400 and/or the semiconductor chip 200 may be secured, and at the same time, the gap region between the adhesive member 300 and the dam structure 400 may be minimized so that occurrence of moisture absorption in the adhesive member 300 is minimized.

In the present embodiment, both side surfaces of the dam structure 400 may have a straight line shape extending along the third direction Z when viewed in cross-section as shown, e.g., in FIG. 11, and an upper surface of the dam structure 400 may have a curved shape that is convex toward the molding member 600. For example, when viewed in cross-section in the X-Z plane as shown in FIG. 11, the upper surface of the dam structure 400 may have a shape of an arc extending from an uppermost point of a first side surface of the dam structure 400 to an uppermost point of a second side surface of the dam structure 400 that is opposite to the first side surface. However, a shape of the dam structure 400 is not limited thereto, and the shape of the dam structure 400 may be variously changed. For example, the upper surface of the dam structure 400 may have a straight line shape, and the dam structure 400 may have a quadrangle shape on a plane. As another example, both side surfaces of the dam structure 400 may have a curved shape.

The dam structure 400 may have a first height h1, and the adhesive member 300 may have a second height h2. Here, the first height h1 of the dam structure 400 means a height along the third direction Z from a lower surface of the dam structure 400 to an upper surface of the dam structure 400 (e.g., to an uppermost point on the upper surface of the dam structure 400), and the second height h2 of the adhesive member 300 means a height along the third direction Z from a lower surface of the adhesive member 300 to an upper surface of the adhesive member 300.

In the present embodiment, the first height h1 may be substantially the same as the second height h2, or may be higher than the second height h2. That is, the upper portion surface of the dam structure 400 may be disposed at substantially the same level as that of an upper portion surface of the adhesive member 300, or may be disposed at a higher level than that of the upper portion surface of the adhesive member 300.

Accordingly, the dam structure 400 may overlap all side surfaces of the adhesive member 300 in the first direction X.

In the present embodiment, the dam structure 400 may include the moisture absorbent described above. Because the dam structure 400 includes the moisture absorbent, the dam structure 400 may absorb moisture even if the dam structure 400 is disposed to be spaced apart from the adhesive member 300. Therefore, moisture permeating from the outside of the semiconductor package 10_4 through the molding member 600 to the adhesive member 300 may be minimized.

According to the semiconductor package 10_4 shown in FIGS. 9 to 11, the dam structure 400 including the moisture absorbent may be disposed to surround the side surfaces of the adhesive member 300. Thus, moisture permeating from the outside of the semiconductor package 10_4 through the molding member 600 to the adhesive member 300 may be alleviated.

Accordingly, the semiconductor e 10_4 may have substantially the same effect as that of the semiconductor package 10 according to the embodiment.

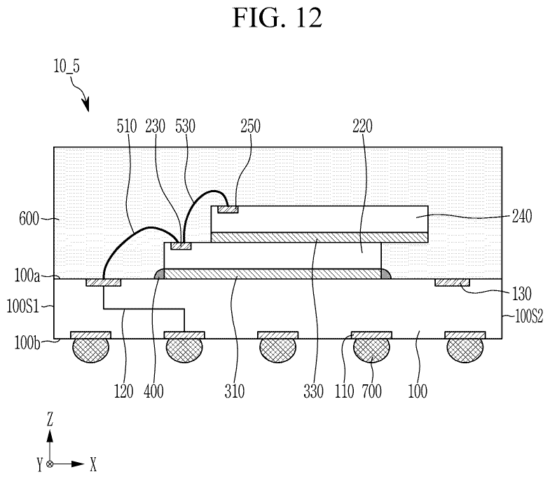

FIGS. 12 to 15 are cross-sectional views of semiconductor packages according to some embodiments.

According to the semiconductor packages 10_5, 10_6, 10_7, and 10_8 shown in FIGS. 12 to 15, unlike the semiconductor package 10_1 according to the embodiment, there is a difference in that the semiconductor packages 10_5, 10_6, 10_7, and 10_8 have a structure in which a plurality of semiconductor chips are stacked on the package substrate 100 and a disposition form of the dam structure 400 is different.

Referring to FIGS. 12 to 15, semiconductor chips 220 and 240 may be sequentially stacked on the first surface 100a of the package substrate 100. The package substrate 100, the first semiconductor chip 220, and the second semiconductor chip 240 may be electrically connected to each other by a wire bonding method.

Although FIGS. 12 to 15 show that the number of semiconductor chips stacked on the package substrate 100 is two, the number of semiconductor chips stacked on the package substrate 100 is not limited thereto, and two or more semiconductor chips may be stacked.

Specifically, the semiconductor packages 10_5, 10_6, 10_7, and 10_8 shown in FIGS. 12 to 15 may include the first semiconductor chip 220 and the second semiconductor chip 240 sequentially stacked on the first surface 100a of the package substrate 100, a first bonding wire 510, and a second bonding wire 530.

The package substrate 100 may include a first side surface 100S1 and a second side surface 100S2 facing each other in the first direction X.

The first semiconductor chip 220 may be disposed on the first surface 100a of the package substrate 100. Although FIGS. 12 to 15 show that the first semiconductor chip 220 is disposed at a central portion of the package substrate 100, a position of the first semiconductor chip 220 is not limited thereto, and may be variously changed. For example, the first semiconductor chip 220 may be disposed closer to any one of the first side surface 100S1 and the second side surface 100S2 of the package substrate 100.

A first adhesive member 310 may be disposed between the first semiconductor chip 220 and the package substrate 100. The first semiconductor chip 220 may be adhered to the first surface 100a of the package substrate 100 by the first adhesive member 310.

The first semiconductor chip 220 may include a first chip pad 230. The first chip pad 230 may be disposed on an upper surface of the first semiconductor chip 220. The first chip pad 230 may be disposed closer to the first side surface 100S1 than to the second side surface 100S2 of the package substrate 100.

The first bonding wire 510 may be connected to the first chip pad 230 and an upper substrate pad 130 of the package substrate 100. The package substrate 100 and the first semiconductor chip 220 may be electrically connected by the first bonding wire 510.

The second semiconductor chip 240 may be mounted on the upper surface of the first semiconductor chip 220. The first semiconductor chip 220 and the second semiconductor chip 240 may have substantially the same size. However, the present disclosure is not limited thereto, and the first semiconductor chip 220 and the second semiconductor chip 240 may have different sizes.

The first semiconductor chip 220 and the second semiconductor chip 240 may be any one of the types of the semiconductor chips described above. For example, the first semiconductor chip 220 and the second semiconductor chip 240 may be the same type of the semiconductor chip. As another example, the first semiconductor chip 220 and the second semiconductor chip 240 may be different types of the semiconductor chips.

The first semiconductor chip 220 and the second semiconductor chip 240 may not be aligned in the third direction Z that is a direction perpendicular to the package substrate 100, and may have an offset stacking structure.

Specifically, the second semiconductor chip 240 may be disposed offset from the first semiconductor chip 220 to one side or the other side in the first direction X. In other words, a central axis of the first semiconductor chip 220 and a central axis of the second semiconductor chip 240 may be disposed to deviate from each other. For example, the second semiconductor chip 240 may be disposed on the upper surface of the first semiconductor chip 220 so that it is closer to the second side surface 100S2 of the package substrate 100 than to the first side surface 100S1 of the package substrate 100.

The second semiconductor chip 240 may have an overhang region that protrudes outward from a side surface of the first semiconductor chip 220. Here, the overhang region of the second semiconductor chip 240 may be a region among regions of the second semiconductor chip 240 that is not supported by the first semiconductor chip 220 and protrudes from the side surface of the first semiconductor chip 220 in the first direction X. In other words, the overhang region of the second semiconductor chip 240 may be a region that does not overlap the first semiconductor chip 220 in the third direction Z that is a vertical direction.

Because the second semiconductor chip 240 is disposed offset from the first semiconductor chip 220, a portion of the first semiconductor chip 220 may overlap the second semiconductor chip 240 in the third direction Z that is the vertical direction, and the remaining portion of the first semiconductor chip 220 may not overlap the second semiconductor chip 240 in the third direction Z that is the vertical direction. Additionally, the second semiconductor chip 240 may not overlap the first chip pad 230 of the first semiconductor chip 220 in the third direction Z that is the vertical direction.

A second adhesive member 330 may be disposed between the first semiconductor chip 220 and the second semiconductor chip 240. The second semiconductor chip 240 may be adhered to the upper surface of the first semiconductor chip 220 by the second adhesive member 330.

A portion of the second adhesive member 330 may be disposed on the upper surface of the first semiconductor chip 220, and the remaining portion of the second adhesive member 330 may be disposed to protrude from the side surface of the first semiconductor chip 220 in the first direction X. That is, the portion of the second adhesive member 330 may be disposed on the upper surface of the first semiconductor chip 220, and the remaining portion of the second adhesive member 330 may be disposed at the overhang region of the second semiconductor chip 240. In other words, the portion of the second adhesive member 330 may overlap the first semiconductor chip 220 and the second semiconductor chip 240 in the third direction Z, and the remaining portion of the second adhesive member 330 may overlap the overhang region of the second semiconductor chip 240 in the third direction Z.

The second semiconductor chip 240 may include a second chip pad 250. The second chip pad 250 may be disposed on an upper surface of the second semiconductor chip 240. The second chip pad 250 may be disposed closer to the first side surface 100S1 among the first side surface 100S1 and the second side surface 100S2 of the package substrate 100.

The second bonding wire 530 may be connected to the first chip pad 230 and the second chip pad 250. The first semiconductor chip 220 and the second semiconductor chip 240 may be electrically connected to each other by the second bonding wire 530.

Accordingly, the package substrate 100, the first semiconductor chip 220, and the second semiconductor chip 240 may be electrically connected to each other by the bonding wires 510 and 530.

The molding member 600 may be disposed on the package substrate 100, and may entirely cover the first surface 100a of the package substrate 100, the semiconductor chips 220 and 240, and the bonding wires 510 and 530.

Hereinafter, disposition of the dam structure 400 in the embodiments shown in FIGS. 12 to 15 will be described.

According to the semiconductor package 10_5 according to the embodiment shown in FIG. 12, the dam structure 400 may be disposed outside (e.g., may border) the first adhesive member 310, and may not be disposed outside the second adhesive member 330. That is, in the present embodiment, the dam structure 400 may be disposed only outside the first adhesive member 310, and may not be disposed outside the second adhesive member 330.

Specifically, in the present embodiment, the dam structure 400 may be disposed on the first surface 100a of the package substrate 100, and may be in direct contact with the first adhesive member 310. In other words, the dam structure 400 may entirely cover a side surface of the first adhesive member 310. However, a shape and a disposition form of the dam structure 400 are not limited thereto, and may be variously changed. For example, as in an embodiment shown in FIG. 3, the dam structure 400 may cover at least a portion of the side surface of the first semiconductor chip 220. As another example, the dam structure 400 may have substantially the same shape as that of the embodiment shown in FIG. 4.

Although not shown in the drawings, in the present embodiment, the dam structure 400 may have a substantially the same disposition form as that of the embodiments shown in FIGS. 6 to 9 on a plane.

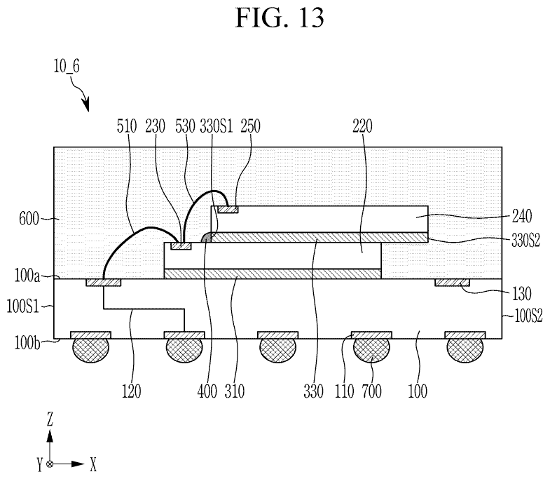

According to the semiconductor package 10_6 according to the embodiment shown in FIG. 13, unlike the embodiment shown in FIG. 12, a dam structure 400 may be disposed outside (e.g., may border) the second adhesive member 330, and may not be disposed outside the first adhesive member 310. That is, in the present embodiment, the dam structure 400 may be disposed only outside the second adhesive member 330, and may not be disposed outside the first adhesive member 310.

Specifically, in the present embodiment, the second adhesive member 330 may include a first side surface 330S1 and a second side surface 330S2 opposite to each other in the first direction X.

The first side surface 330S1 of the second adhesive member 330 may be disposed on the upper surface of the first semiconductor chip 220. That is, the first side surface 330S1 of the second adhesive member 330 may overlap the upper surface of the first semiconductor chip 220 in the third direction Z.

The second side surface 330S2 of the second adhesive member 330 may be disposed to protrude from a side surface of the first semiconductor chip 220 and a side surface of the first adhesive member 310 in the first direction X. That is, the second side surface 330S2 of the second adhesive member 330 may be disposed at an overhang region of the second semiconductor chip 240. In other words, the second side surface 330S2 of the second adhesive member 330 may not overlap the first semiconductor chip 220 and the first adhesive member 310 in the third direction Z.

In the present embodiment, the dam structure 400 may be disposed on the upper surface of the first semiconductor chip 220. The dam structure 400 may be disposed outside (e.g., may border) a side surface of the second adhesive member 330 disposed on the upper surface of the first semiconductor chip 220 among side surfaces of the second adhesive member 330.

The dam structure 400 may be disposed outside the first side surface 330S1 of the second adhesive member 330, and may not be disposed outside the second side surface 330S2. In other words, the dam structure 400 may be disposed only outside the first side surface 330S1 of the second adhesive member 330.

The dam structure 400 may be in contact with the first side surface 330S1 of the second adhesive member 330. The dam structure 400 may entirely cover the first side surface 330S1 of the second adhesive member 330. However, a shape and a disposition form of the dam structure 400 are not limited thereto, and may be variously changed. For example, the dam structure 400 may be disposed at a predetermined distance along the first direction X from the first side surface 330S1 of the second adhesive member 330. As another example, the dam structure 400 may cover at least a portion of the first side surface 330S1 of the second adhesive member 330 and a side surface of the second semiconductor chip 240.

Although not shown in FIG. 13, in some embodiments, if a width of the second adhesive member 330 and a width of the second semiconductor chip 240 along the second direction Y are smaller than a width of the first semiconductor chip 220 along the second direction Y, the dam structure 400 may cross the first side surface 330S1 of the second adhesive member 330, and may entirely cover side surfaces of the second adhesive member 330 extending in the first direction X.

Additionally, in some embodiments, if widths of the second adhesive member 330 and widths of the second semiconductor chip 240 along the first direction X and the second direction Y are smaller than a width of the first semiconductor chip 220 along the first direction X and the second direction Y, the dam structure 400 may extend along an outer circumference of the second adhesive member 330, and may cover all the side surfaces of the second adhesive member 330.

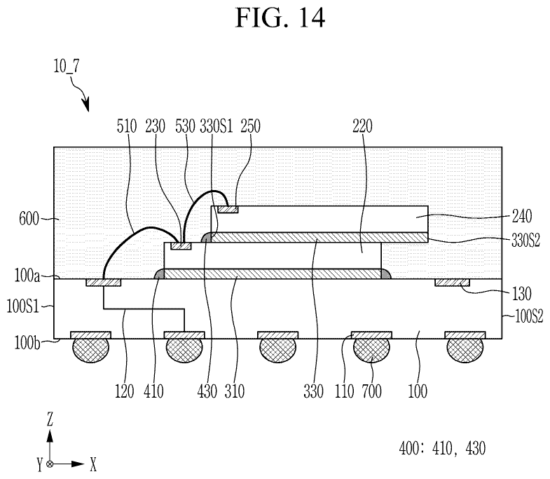

According to the semiconductor package 10_7 according to the embodiment shown in FIG. 14, unlike the embodiment shown in FIG. 12, the dam structure 400 may be disposed outside (e.g., may border) both the first adhesive member 310 and the second adhesive member 330.

Specifically, the dam structure 400 may include a first dam structure 410 (e.g., a first portion) disposed on the first surface 100a of the package substrate 100 and a second dam structure 430 (e.g., a second portion) disposed on an upper surface of the first semiconductor chip 220. The first dam structure 410 may be disposed so as not to overlap the second dam structure 430 in the third direction Z that is the vertical direction.

The description of the dam structure 400 according to the embodiment shown in FIG. 12 may be substantially and equally applied to the first dam structure 410 according to the present embodiment, and the description of the dam structure 400 according to the embodiment shown in FIG. 13 may be substantially and equally applied to the second dam structure 430 according to the present embodiment, so that a detailed description thereof is omitted.

In the present embodiment, the first dam structure 410 is shown to be in contact with the first adhesive member 310 and the second dam structure 430 is shown to be in contact with the second adhesive member 330, but dispositions of the first dam structure 410 and the second dam structure 430 are not limited thereto, and may be variously changed.

For example, the first dam structure 410 may be disposed at a predetermined distance in the first direction X from the first adhesive member 310, and the second dam structure 430 may be in contact with the second adhesive member 330. As another example, the first dam structure 410 may be in contact with the first adhesive member 310, and the second dam structure 430 may be disposed at a predetermined distance from the second adhesive member 330 in the first direction X. As another example, each of the first dam structure 410 and the second dam structure 430 may be disposed at a predetermined distance from each of the first adhesive member 310 and the second adhesive member 330 in the first direction X.

In the present embodiment, the first dam structure 410 and the second dam structure 430 may include any one of the above-described materials, and the first dam structure 410 and the second dam structure 430 may include the same material. However, the present disclosure is not limited thereto, and the first dam structure 410 and the second dam structure 430 may include different materials.

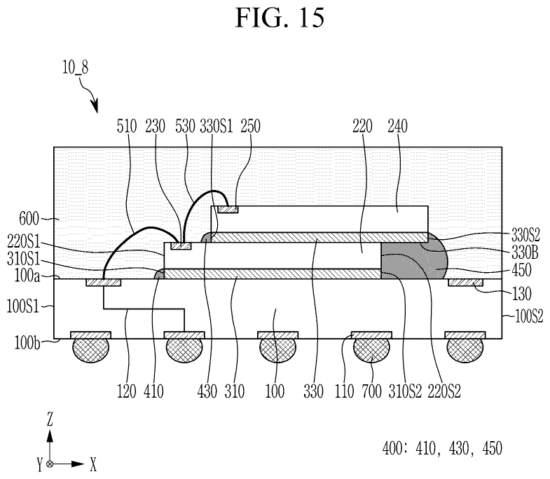

According to the semiconductor package 10_8 according to the embodiment shown in FIG. 15, unlike the embodiment shown in FIG. 14, there is a difference in that the dam structure 400 entirely covers the second adhesive member 330 disposed at an overhang region of the second adhesive member 330.

Specifically, the first adhesive member 310 may include a first side surface 310S1 and a second side surface 310S2 opposite to each other in the first direction X, and the second adhesive member 330 may include a first side surface 330S1 and a second side surface 330S2 opposite to each other in the first direction X.

The first side surface 310S1 of the first adhesive member 310 may be disposed to further protrude from the first side surface 330S1 of the second adhesive member 330 toward one side of the first direction X, and the second side surface 330S2 of the second adhesive member 330 may be disposed to further protrude from the second side surface 310S2 of the first adhesive member 310 toward the other side of the first direction X.

In the present embodiment, the dam structure 400 may include a first dam structure 410 disposed outside the first side surface 310S1 of the first adhesive member 310, a second dam structure 430 disposed outside the first side surface 330S1 of the second adhesive member 330, and a third dam structure 450 disposed outside both the second side surface 310S2 of the first adhesive member 310 and the second side surface 330S2 of the second adhesive member 330.

Specifically, the first dam structure 410 may be in contact with the first side surface 310S1 of the first adhesive member 310, and may entirely cover the first side surface 310S1 of the first adhesive member 310.

The description of the second dam structure 430 according to the embodiment shown in FIG. 14 may be substantially and equally applied to the second dam structure 430 according to the present embodiment, so that a detailed description thereof is omitted.

The third dam structure 450 may be disposed on the first surface 100a of the package substrate 100, and may cover the second side surface 310S2 of the first adhesive member 310, a side surface of the first semiconductor chip 220, and both the second side surface 330S2 and a lower portion surface 330B of the second adhesive member 330.

The third dam structure 450 may be disposed in a space between a portion of the second adhesive member 330 that is disposed at an overhang region of the second semiconductor chip 240 and the package substrate 100. In other words, the third dam structure 450 may be disposed to fill the space formed between the second adhesive member 330 and the package substrate 100 because the first semiconductor chip 220 and the second adhesive member 330 are shifted and stacked.

Accordingly, the third dam structure 450 may be in contact with the side surface of the first semiconductor chip 220 disposed adjacent to the second side surface 310S2 of the first adhesive member 310 and a second side surface 100S2 of the package substrate 100, and may entirely cover the second side surface 310S2 of the first adhesive member 310 and the side surface of the first semiconductor chip 220.

The third dam structure 450 may be in contact with the lower surface 330B of the second adhesive member 330 and the second side surface 330S2 of the second adhesive member 330 that protrude from the second side surface 310S2 of the first adhesive member 310 in the first direction X, and may entirely cover the lower surface 330B and the second side surface 330S2 of the second adhesive member 330 disposed at the overhang region.

A width of the third dam structure 450 along the first direction X may be greater than a width of each of the first and second dam structures 410 and 430 along the first direction X. Additionally, a height of the third dam structure 450 along the third direction Z may be greater than both the width of each of the first and second dam structures 410 and 430 along the first direction X and a height of each of the first and second dam structures 410 and 430 along the third direction Z. However, a width and a height relationship of the first to third dam structures 410, 430, and 450 are not limited thereto, and may be variously changed.

In the present embodiment, the first dam structure 410, the second dam structure 430, and the third dam structure 450 may include any one of the materials described above, and the first dam structure 410, the second dam structure 430, and the third dam structure 450 may include the same material. However, the present disclosure is not limited thereto, and at least one of the first dam structure 410, the second dam structure 430, and the third dam structure 450 may include different materials. For example, the first dam structure 410 and the second dam structure 430 may include the same material, and the third dam structure 450 may include a different material from those of the first and second dam structures 410 and 430. The first dam structure 410, the second dam structure 430, and the third dam structure 450 may be formed integrally with each other or separately from each other.

Although not shown in FIG. 15, the first dam structure 410 may entirely cover side surfaces of the first adhesive member 310 that cross the first side surface 310S1 of the first adhesive member 310 to extend in the first direction X. That is, some of the side surfaces of the first adhesive member 310 may be covered by the first dam structure 410, and the remaining side surfaces of the first adhesive member 310 may be covered by the third dam structure 450.

In some embodiments, if a width of the second adhesive member 330 and a width of the second semiconductor chip 240 along the second direction Y are smaller than a width of the first semiconductor chip 220 along the second direction Y, the second dam structure 430 may entirely cover side surfaces of the second adhesive member 330 that cross the first side surface 330S1 of the second adhesive member 330 to extend in the first direction X. That is, some of the side surfaces of the second adhesive member 330 may be covered by the second dam structure 430, and the remaining side surfaces of the second adhesive member 330 may be covered by the third dam structure 450.

According to the semiconductor packages 10_5, 10_6, 10_7, and 10_8 shown in FIGS. 12 to 15, the dam structure 400 may cover some of side surfaces of the adhesive members 310 and 330 by forming the dam structure 400 on the side surface or some of the side surfaces vulnerable to moisture absorption among the side surfaces of the first adhesive member 310 and the side surfaces of the second adhesive member 330.

Accordingly, because moisture permeating from the outside of the semiconductor packages 10_5, 10_6, 10_7, and 10_8 through the molding member 600 to the first adhesive member 310 and/or the second adhesive member 330 is minimized, the semiconductor packages 10_5, 10_6, 10_7, and 10_8 may have substantially the same effect as that of the semiconductor package 10 according to the embodiment.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the inventive concept.

What is claimed is:

1. A semiconductor package comprising:
a package substrate including a substrate pad;
a semiconductor chip on the package substrate, the semiconductor chip including a chip pad;
a bonding wire that connects the substrate pad to the chip pad;
an adhesive member between the package substrate and the semiconductor chip; and
a dam extending along a side surface of the adhesive member and surrounding at least some of side surfaces of the adhesive member,
wherein a height of the dam is greater than or equal to a height of the adhesive member.

2. The semiconductor package of claim 1, wherein the dam surrounds all the side surfaces of the adhesive member and is in contact with the side surfaces of the adhesive member.

3. The semiconductor package of claim 2, wherein the height of the dam is greater than the height of the adhesive member, and the dam is in contact with at least some of side surfaces of the semiconductor chip.

4. The semiconductor package of claim 2, wherein the dam comprises:
a first side surface that contacts the adhesive member; and
a second side surface opposite to the first side surface,
wherein the second side surface includes a curved surface.

5. The semiconductor package of claim 4, wherein the dam includes a metal material.

6. The semiconductor package of claim 4, wherein the dam includes at least one of a moisture absorbent, an epoxy resin, silicon, polyurethane, polycarbonate, polypropylene, and polyethylene.

7. The semiconductor package of claim 1, wherein the dam is spaced apart from the adhesive member.

8. The semiconductor package of claim 7, wherein a distance between the dam and the adhesive member is about 20 μm to 30 μm.

9. The semiconductor package of claim 7, wherein the dam includes a moisture absorbent.

10. The semiconductor package of claim 1, wherein the adhesive member includes a first side surface and a second side surface opposite to the first side surface, and the dam includes a first portion extending along the first side surface of the adhesive member and a second portion extending along the second side surface of the adhesive member.

11. The semiconductor package of claim 1, wherein the adhesive member includes a first side surface extending in a first direction and a second side surface extending in a second direction that crosses the first direction, and the dam includes a first portion extending along the first side surface of the adhesive member and a second portion extending along the second side surface of the adhesive member.

12. The semiconductor package of claim 11, wherein the adhesive member includes a third side surface opposite to the second side surface in the first direction, and the dam further includes a third portion extending along the third side surface of the adhesive member.

13. A semiconductor package comprising:
a package substrate including a substrate pad;
a first semiconductor chip on the package substrate, the first semiconductor chip including a first chip pad;
a first adhesive member between the first semiconductor chip and the package substrate;
a first bonding wire connecting the substrate pad to the first chip pad;
a second semiconductor chip including a second chip pad, the second semiconductor chip being on the first semiconductor chip;
a second adhesive member between the first semiconductor chip and the second semiconductor chip;
a second bonding wire connecting the first chip pad to the second chip pad; and
a dam bordering at least one of side surfaces of the first adhesive member and side surfaces of the second adhesive member.

14. The semiconductor package of claim 13, wherein the dam includes a first portion on the package substrate and bordering at least one of the side surfaces of the first adhesive member.

15. The semiconductor package of claim 14, wherein the dam further includes a second portion on an upper surface of the first semiconductor chip, the second portion bordering at least one of the side surfaces of the second adhesive member.

16. The semiconductor package of claim 15, wherein the second adhesive member includes a side surface that protrudes from a side surface of the first semiconductor chip, and
wherein the dam further includes a third portion on the package substrate, the third portion covering a lower surface of the second adhesive member, the protruding side surface of the second adhesive member, a side surface of the first adhesive member, and a side surface of the first semiconductor chip.

17. The semiconductor package of claim 16, wherein the first portion of the dam is in contact with the first adhesive member, the second portion of the dam is in contact with the second adhesive member, and the third portion of the dam is in contact with the first adhesive member, the first semiconductor chip, and the second adhesive member.

18. The semiconductor package of claim 13, wherein the dam is only on an upper surface of the first semiconductor chip and borders at least one of the side surfaces of the second adhesive member.

19. The semiconductor package of claim 13, wherein the dam includes at least one of a metal material, a moisture absorbent, an epoxy resin, silicon, polyurethane, polycarbonate, polypropylene, and polyethylene.

20. A semiconductor package comprising:
a package substrate including a substrate pad;
a semiconductor chip on the package substrate, the semiconductor chip including a chip pad;
a bonding wire that connects the substrate pad to the chip pad;
an adhesive member between the package substrate and the semiconductor chip;
a dam extending along a side surface of the adhesive member and surrounding at least some of side surfaces of the adhesive member; and
a molding member that entirely covers the semiconductor chip and the dam,
wherein the dam includes a metal material, a height of the dam is greater than or equal to a height of the adhesive member, and a side surface of the dam includes a curved surface.
